(19) United States
(12) Patent Application Publication
(10) Pub. No.: US 2026/0368395 A1
(43) Pub. Date: Nov. 19, 2026

(54) METHOD AND APPARATUS FOR INTEGRATED MANAGEMENT OF FACILITIES BASED ON DIGITAL TWIN

(71) Applicants: KOREA AIRPORTS CORPORATION, Seoul (KR); COSPEC INNOLAB CO., LTD., Seoul (KR)

(72) Inventors: Sunbae MOON, Seoul (KR); Euisoo JUNG, Seoul (KR); Jaeho JANG, Gimpo-si Gyeonggi-do (KR); Gutaek KIM, Seoul (KR)

(73) Assignees: KOREA AIRPORTS CORPORATION, Seoul (KR); COSPEC INNOLAB CO., LTD., Seoul (KR)

(21) Appl. No.: 19/515,189

(22) PCT Filed: Jun. 10, 2024
(86) PCT No.: PCT/KR2024/007879

§ 371 Date: Feb. 27, 2026

(30) Foreign Application Priority Data
Aug. 30, 2023 (KR) 10-2023-0114095

(51) Int. Cl. G06F 30/20; G06F 30/13

(52) U.S. Cl. CPC G06F 30/20; G06F 30/13

(57) ABSTRACT

The present invention relates to a method for integrated management of facilities based on a digital twin. The method for integrated management of facilities based on a digital twin comprises: obtaining digital twin model data generated based on a first criterion including a modeling rule and a second criterion including a shape and an attribute of an object; determining whether the obtained digital twin model data satisfies a quality criterion using a plurality of rules; and registering the digital twin model data in a database when the digital twin model data is determined to satisfy the quality criterion.

### TECHNICAL FIELD

The present invention relates to a method and apparatus for integrated management of facilities based on a digital twin, and more particularly, to a method and apparatus for integrated management of facilities based on a digital twin for managing facilities through registration of a precise digital twin model.

### BACKGROUND ART

A digital twin may refer to an implementation that represents an object or a system existing in the real world as an identical digital data model on a computer to enable real-time interaction. For example, the use of a digital twin has an advantage of monitoring various situations that may occur in reality or performing a prior simulation via a computer; therefore, efforts are currently being made to introduce digital twins in various industrial fields.

Meanwhile, in order to perform monitoring of the real world through a digital twin model, it is important to accurately generate the digital twin model without errors. However, a digital twin model includes numerous 3D objects, and there is a problem in that it is not easy to detect which object among the numerous 3D objects has an error.

### DETAILED DESCRIPTION OF INVENTION

### Technical Problem

The present invention provides a method for integrated management of facilities based on a digital twin, a computer program stored in a computer-readable medium, a computer-readable medium storing a computer program, and an apparatus (system) to solve the above-mentioned problems.

### Technical Solution

The present invention may be implemented in various forms, including a method, an apparatus (system), a computer program stored in a computer-readable medium, or a computer-readable medium storing the computer program.

According to an embodiment of the present invention, a method for integrated management of facilities based on a digital twin, performed by at least one processor, comprises: obtaining digital twin model data generated based on a first criterion including a modeling rule and a second criterion including a shape and an attribute of an object; determining whether the obtained digital twin model data satisfies a quality criterion using a plurality of rules; and registering the digital twin model data in a database when the digital twin model data is determined to satisfy the quality criterion.

According to an embodiment of the present invention, the method further comprises performing monitoring of an actual facility associated with the digital twin model data based on the digital twin model data registered in the database.

According to an embodiment of the present invention, the determining of whether the obtained digital twin model data satisfies the quality criterion comprises determining whether each object included in the digital twin model data satisfies at least a portion of the plurality of rules.

According to an embodiment of the present invention, the determining of whether each object included in the digital twin model data satisfies at least a portion of the plurality of rules comprises: searching for an ID of a first object included in the digital twin model data; recognizing a shape and an attribute of the object based on the searched ID of the first object; and determining whether the first object satisfies the quality criterion based on a first set of rules corresponding to the recognized shape and attribute of the first object among the plurality of rules.

According to an embodiment of the present invention, the method further comprises, when it is determined that the digital twin model data does not satisfy the quality criterion, extracting a second object that does not satisfy the quality criterion from among the respective objects included in the digital twin model data, and generating a quality review report visualizing an image of the extracted second object and data related to a quality review result of the second object.

According to an embodiment of the present invention, the method further comprises, when the shape and the attribute of the second object are changed, obtaining modified digital twin model data and determining whether the modified digital twin model data satisfies the quality criterion using the plurality of rules.

According to an embodiment of the present invention, the digital twin model data is associated with an actual facility. The method further comprises updating the digital twin model data when a change occurs in the facility.

According to an embodiment of the present invention, the updating of the digital twin model data comprises: obtaining sensor data corresponding to the change in the facility; extracting a third object associated with the sensor data from among the respective objects included in the digital twin model data; and updating the extracted third object based on the obtained sensor data.

According to an embodiment of the present invention, the method further comprises, in response to the digital twin model data being updated, determining whether the updated digital twin model data satisfies the quality criterion using the plurality of rules.

A computer program stored in a computer-readable recording medium for executing the method according to an embodiment of the present invention on a computer is provided.

A computing apparatus according to an embodiment of the present invention comprises a communication module, a memory, and at least one processor connected to the memory and configured to execute at least one computer-readable program included in the memory. The at least one program includes instructions for: obtaining digital twin model data generated based on a first criterion including a modeling rule and a second criterion including a shape and an attribute of an object; determining whether the obtained digital twin model data satisfies a quality criterion using a plurality of rules; and registering the digital twin model data in a database when the digital twin model data is determined to satisfy the quality criterion.

According to an embodiment of the present invention, the at least one program includes instructions for performing monitoring of an actual facility associated with the digital twin model data based on the digital twin model data registered in the database.

According to an embodiment of the present invention, the at least one program further includes instructions for determining whether each object included in the digital twin model data satisfies at least a portion of the plurality of rules.

According to an embodiment of the present invention, the at least one program further includes instructions for: searching for an ID of a first object included in the digital twin model data; recognizing a shape and an attribute of the object based on the searched ID of the first object; and determining whether the first object satisfies the quality criterion based on a first set of rules corresponding to the recognized shape and attribute of the first object among the plurality of rules.

According to an embodiment of the present invention, the at least one program further includes instructions for, when it is determined that the digital twin model data does not satisfy the quality criterion, extracting a second object that does not satisfy the quality criterion from among the respective objects included in the digital twin model data, and generating a quality review report visualizing an image of the extracted second object and data related to a quality review result of the second object.

According to an embodiment of the present invention, the at least one program further includes instructions for, when the shape and the attribute of the second object are changed, obtaining modified digital twin model data and determining whether the modified digital twin model data satisfies the quality criterion using the plurality of rules.

According to an embodiment of the present invention, the digital twin model data is associated with an actual facility. The at least one program further includes instructions for updating the digital twin model data when a change occurs in the facility.

According to an embodiment of the present invention, the at least one program further includes instructions for: obtaining sensor data corresponding to the change in the facility; extracting a third object associated with the sensor data from among the respective objects included in the digital twin model data; and updating the extracted third object based on the obtained sensor data.

According to an embodiment of the present invention, the at least one program further includes instructions for, in response to the digital twin model data being updated, determining whether the updated digital twin model data satisfies the quality criterion using the plurality of rules.

### Advantageous Effects

In various embodiments of the present invention, a computing apparatus may automatically perform a quality review of complex digital twin model data to detect an error or provide detected information to a user, and may perform effective facility management by automatically reflecting a change in an actual facility associated with the digital twin model.

In various embodiments of the present invention, a computing apparatus may extract only an object in which an error occurs from among numerous objects constituting digital twin model data to generate and provide a quality review report to a user, and the user may simply change or modify the digital twin model data using the quality review report in which corresponding details are reflected.

The effects of the present invention are not limited to the effects mentioned above, and other effects not mentioned will be clearly understood by those skilled in the art to which the present invention pertains from the descriptions in the claims.

### BRIEF DESCRIPTION OF DRAWINGS

Embodiments of the present invention will be described with reference to the accompanying drawings described below, wherein like reference numerals refer to like elements, but are not limited thereto.

FIG. 1 is a functional block diagram illustrating an internal configuration of a computing apparatus according to an embodiment of the present invention.

FIG. 2 is an exemplary diagram illustrating a portion of digital twin model data according to an embodiment of the present invention.

FIG. 3 is an exemplary diagram illustrating a portion of a quality review report according to an embodiment of the present invention.

FIG. 4 is a diagram illustrating an example of a method for integrated management of facilities based on a digital twin according to an embodiment of the present invention.

FIG. 5 is a block diagram illustrating an internal configuration of a computing apparatus according to an embodiment of the present invention.

### MODES FOR CARRYING OUT THE INVENTION

Hereinafter, specific details for carrying out the present invention will be described in detail with reference to the accompanying drawings. However, in the following description, specific descriptions of well-known functions or configurations will be omitted if they are likely to unnecessarily obscure the gist of the present invention.

In the accompanying drawings, identical or corresponding components are assigned the same reference numerals. Additionally, in the description of the embodiments below, a redundant description of identical or corresponding components may be omitted. However, even if a description of a component is omitted, it is not intended that such component is not included in any embodiment.

The advantages and features of the disclosed embodiments, and methods for achieving the same, will become apparent with reference to the embodiments described below in conjunction with the accompanying drawings. However, the present invention is not limited to the embodiments disclosed below but may be embodied in various different forms. These embodiments are provided merely to make the disclosure of the present invention complete and to fully inform those of ordinary skill in the art of the scope of the invention.

The terms used in this specification will be briefly described, and the disclosed embodiments will be described in detail. The terms used herein have been selected from general terms that are currently widely used, while taking into account their functions in the present invention. However, these terms may change depending on the intent of a person skilled in the relevant field, court precedents, or the emergence of new technologies. In addition, in certain cases, there are terms arbitrarily selected by the applicant, and in such cases, the meanings thereof will be described in detail in the corresponding description of the invention. Therefore, the terms used in the present invention should be defined based on their meanings and the overall content of the present invention, rather than their simple names.

In this specification, singular expressions include plural expressions unless the context clearly indicates otherwise. In addition, plural expressions include singular expressions unless the context clearly indicates otherwise. Throughout this specification, when it is stated that a part “comprises” a component, this means that it may further include other components, not that it excludes other components, unless otherwise stated.

In the present invention, terms such as “comprise” and “comprising” may indicate the presence of features, steps, operations, elements, and/or components, but such terms do not exclude the addition of one or more other functions, steps, operations, elements, components, and/or combinations thereof.

In the present invention, when a particular component is referred to as being “coupled,” “combined,” “connected,” or “reacting” with any other component, the particular component may be directly coupled, combined, and/or connected to, or react with, the other component, but is not limited thereto. For example, there may be one or more intermediate components between a particular component and another component. Additionally, in the present invention, “and/or” may include each of one or more of the listed items or a combination of at least a portion of one or more of the listed items.

In the present invention, terms such as “first” and “second” are used to distinguish specific components from other components, and the components described above are not limited by these terms. For example, the “first” component may be an element of the same or similar form as the “second” component.

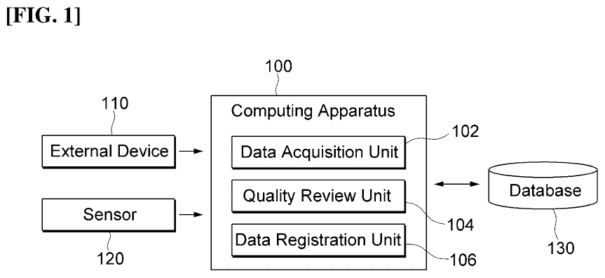

FIG. 1 is a functional block diagram illustrating an internal configuration of a computing apparatus 100 according to an embodiment of the present invention. According to an embodiment, the computing apparatus 100 is an arbitrary apparatus for performing registration and management of a digital twin model and integrated management of an actual facility based on the digital twin model, and may include a data acquisition unit 102, a quality review unit 104, a data registration unit 106, and the like. Additionally, the computing apparatus 100 communicates with an external device 110, a sensor 120 associated with the facility, and the like, and may exchange data and/or information necessary for integrated management of the facility.

According to an embodiment, the data acquisition unit 102 of the computing apparatus 100 may acquire digital twin model data generated based on a first criterion including modeling rules (for example, modeling guidelines) and a second criterion including a shape and an attribute of an object (for example, a standard information management system) from an external device 110 (for example, a user terminal) of a user. Here, the first criterion including modeling rules represents guidelines for creating BIM (building information modeling) design drawings, and may include minimum requirements for architectural design permits. In addition, the second criterion including the shape and the attribute of the object predefines types, classification codes, and the like of BIM model objects such as columns, floors, and stairs, and may include attribute information representing features or properties of the object and shape information representing a shape or a state of the object. That is, the user may generate digital twin model data so as to conform to the first criterion and the second criterion, and may transmit the generated data to the data acquisition unit 102 through the external device 110.

When the digital twin model data is acquired in this manner, the quality review unit 104 of the computing apparatus 100 may determine whether the acquired digital twin model data satisfies a quality criterion using a plurality of rules. That is, the quality review unit 104 may determine whether the digital twin model data has been created to comply with the first criterion and the second criterion. Here, the plurality of rules are predefined through internal functions in a script manner, and may represent rules for checking, for example, (i) whether a width of a staircase object is 1.5 m or more, (ii) whether a height of a column object is 2 m or more, and the like.

According to an embodiment, the quality review unit 104 may determine whether each object included in the digital twin model data satisfies at least a portion of the plurality of rules. To this end, the quality review unit 104 may first search for an ID of each object included in the digital twin model data, and recognize a shape and an attribute of the object based on the searched ID of the object. For example, all objects included in the digital twin model data may have a unique ID, and the quality review unit 104 may recognize a corresponding object through the ID of the object, and may recognize which BIM model object (for example, a column, a floor, a staircase, and the like) the corresponding object is and what size, shape, and the like it has, through attribute information and shape information of the object corresponding to the ID.

Then, the quality review unit 104 may determine whether the corresponding object satisfies the quality criterion based on a first set of rules corresponding to the recognized shape and attribute of the object among the plurality of rules. For example, when the recognized object is a staircase object having a specific width, the quality review unit 104 may extract a first set of rules corresponding to the staircase object from among the plurality of rules, and review whether the corresponding object satisfies each rule included in the first set of rules. That is, the plurality of rules may be divided into a plurality of sets according to the shape and the attribute of the object.

According to an embodiment, when it is determined that the digital twin model data does not satisfy the quality criterion, the quality review unit 104 may extract an object that does not satisfy the quality criterion from among the respective objects included in the digital twin model data, and may generate a quality review report visualizing an image of the extracted corresponding object and data related to a quality review result of the corresponding object. The quality review report generated in this manner may be transmitted to the external device 110. Then, the data acquisition unit 102 may acquire modified digital twin model data in which an error of the corresponding object is changed by the user, and the quality review unit 104 may re-determine whether the modified digital twin model data satisfies the quality criterion. Such a process may be repeatedly performed until all objects included in the digital twin model data satisfy the quality criterion.

According to an embodiment, when the quality review unit 104 determines that the digital twin model data satisfies the quality criterion, the data registration unit 106 may finally register the digital twin model data satisfying the quality criterion in a database 130. In this case, the computing apparatus 100 may perform monitoring and/or simulation of an actual facility associated with the digital twin model data based on the digital twin model data registered in the database 130.

Additionally or alternatively, when a change occurs in an actual facility associated with the digital twin model data, the computing apparatus 100 may update the digital twin model data. For example, the computing apparatus 100 may acquire sensor data corresponding to a change in the actual facility from a sensor 120, and extract an object associated with the sensor data from among the respective objects included in the digital twin model data. Then, the computing apparatus 100 may update the extracted corresponding object based on the acquired sensor data. In response to the update being performed in this manner, the quality review unit 104 may re-determine whether the updated digital twin model data satisfies the quality criterion.

In FIG. 1, respective functional components included in the computing apparatus 100 are described separately, but this is merely to facilitate understanding of the invention, and one computing device may perform two or more functions. With such a configuration, the computing apparatus 100 may automatically perform a quality review of complex digital twin model data to detect an error or provide detected information to a user, and may perform effective facility management by automatically reflecting a change in an actual facility associated with the digital twin model.

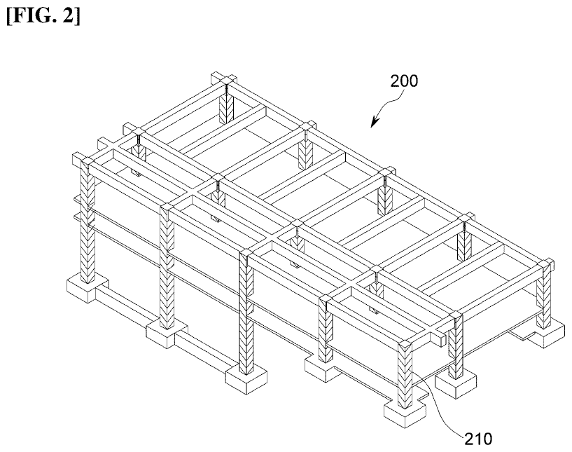

FIG. 2 is an exemplary diagram illustrating a portion of digital twin model data 200 according to an embodiment of the present invention. As illustrated, the digital twin model data (or digital twin model) 200 may be configured to include a plurality of BIM model objects such as columns, floors, and roof members. In this case, each object included in the digital twin model data 200 may be associated with data representing an ID, attribute information, and/or shape information.

As described above, when the computing apparatus 100 of FIG. 1 receives the digital twin model data 200, the computing apparatus 100 may perform a quality review of the received digital twin model data 200. For example, the computing apparatus may select a first object 210 included in the digital twin model data 200 and search for an ID of the selected first object 210. Then, the computing apparatus may recognize a shape and an attribute of the first object 210 based on the searched ID of the first object 210. That is, information on the first object 210, the ID of the first object 210, and the shape and the attribute of the first object 210 on the digital twin model data 200 may be managed in association, and the computing apparatus may extract and recognize the shape and the attribute associated with the first object 210 through the ID of the first object 210.

In this case, the computing apparatus may identify a type, a shape, and the like of the first object 210 using the recognized shape and attribute of the first object 210, and may extract a rule for quality review of the corresponding object from among the plurality of rules. Here, the plurality of rules may be generated to reflect the first criterion including the modeling rule and the second criterion including the shape and the attribute of the object. Then, the computing apparatus may determine whether the shape and the attribute of the first object 210 conform to a criterion corresponding to each rule. When the quality review of the first object 210 is completed in this manner, the computing apparatus may inspect other objects included in the digital twin model data 200.

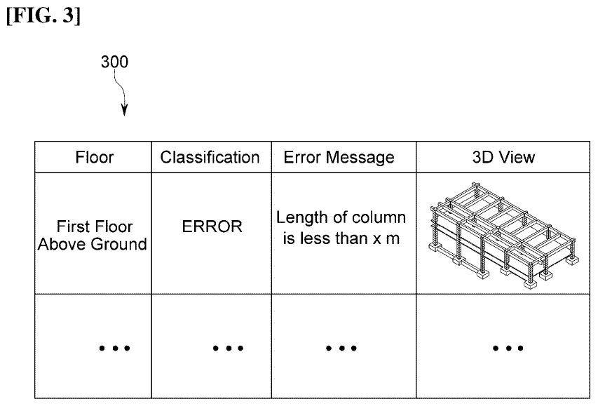

FIG. 3 is an exemplary diagram illustrating a portion of a quality review report 300 according to an embodiment of the present invention. As described above, when it is determined that the digital twin model data does not satisfy the quality criterion, the computing apparatus 100 of FIG. 1 may extract an object that does not satisfy the quality criterion from among the respective objects included in the digital twin model data, and may generate a quality review report 300 visualizing an image of the extracted object and data related to a quality review result of the object.

As illustrated in FIG. 3, the quality review report 300 may include a floor where the corresponding object is located in the facility, a classification, an error message, a 3D view including the corresponding object, and the like. That is, the computing apparatus may automatically extract an object in which an error occurs and a content of the error, and then visualize and provide the same to the user. In this case, the user may check the provided quality review report 300 and modify the digital twin model data by changing the attribute and/or the shape of the object in which the error occurs.

When acquiring the modified digital twin model data in this manner, the computing apparatus may search for an ID of each object determined to have an error among all objects, and may re-perform the quality review only for the searched objects. With such a configuration, the computing apparatus may extract only an object in which an error occurs among numerous objects constituting the digital twin model data to generate and provide the quality review report 300 to the user, and the user may simply change or modify the digital twin model data using the quality review report 300 in which corresponding details are reflected.

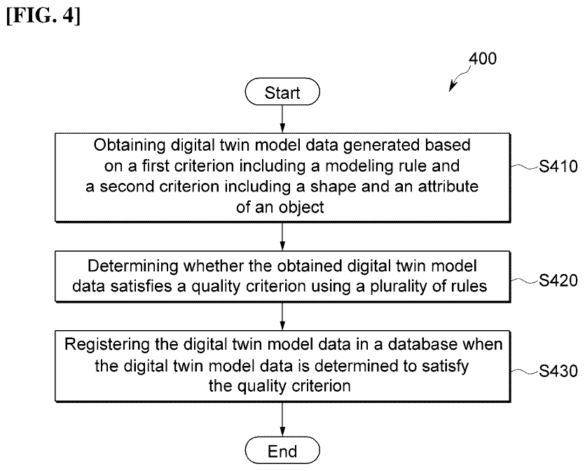

FIG. 4 is a diagram illustrating an example of a method 400 for integrated management of facilities based on a digital twin according to an embodiment of the present invention. The method 400 for integrated management of facilities based on a digital twin may be performed by at least one processor (e.g., at least one processor of a computing apparatus). The method 400 for integrated management of facilities based on a digital twin may be initiated by the processor obtaining digital twin model data generated based on a first criterion including a modeling rule and a second criterion including a shape and an attribute of an object (S410).

The processor may determine whether the obtained digital twin model data satisfies a quality criterion using a plurality of rules (S420). In this case, the processor may determine whether each object included in the digital twin model data satisfies at least a portion of the plurality of rules. For example, the processor may search for an ID of a first object included in the digital twin model data, recognize a shape and an attribute of the object based on the searched ID of the first object, and determine whether the first object satisfies the quality criterion based on a first set of rules corresponding to the recognized shape and attribute of the first object among the plurality of rules.

When it is determined that the digital twin model data satisfies the quality criterion, the processor may register the digital twin model data in a database (S430). In this case, the processor may perform monitoring of an actual facility associated with the digital twin model data based on the digital twin model data registered in the database.

Additionally or alternatively, when it is determined that the digital twin model data does not satisfy the quality criterion, the processor may extract a second object that does not satisfy the quality criterion from among the respective objects included in the digital twin model data, and may generate a quality review report visualizing an image of the extracted second object and data related to a quality review result of the second object. Accordingly, when the shape and the attribute of the second object are changed, the processor may obtain modified digital twin model data and determine whether the modified digital twin model data satisfies the quality criterion using the plurality of rules.

The processor may update the digital twin model data when a change occurs in an actual facility associated with the digital twin model data. For example, the processor may acquire sensor data corresponding to a change in the actual facility, extract a third object associated with the sensor data from among the respective objects included in the digital twin model data, and update the extracted third object based on the acquired sensor data. In response to the digital twin model data being updated in this manner, the processor may determine whether the updated digital twin model data satisfies the quality criterion using the plurality of rules.

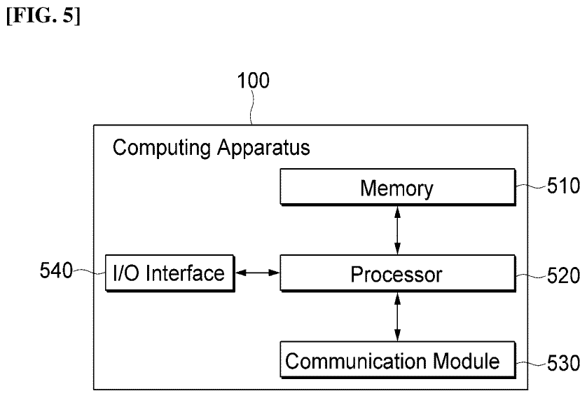

FIG. 5 is a block diagram illustrating an internal configuration of a computing apparatus 100 according to an embodiment of the present invention. The computing apparatus 100 may include a memory 510, a processor 520, a communication module 530, and an input/output interface 540, and as illustrated in FIG. 5, the computing apparatus 100 may be configured to communicate information and/or data through a network using the communication module 530.

The memory 510 may include an arbitrary non-transitory computer-readable recording medium. According to an embodiment, the memory 510 may include a permanent mass storage device such as a random access memory (RAM), a read only memory (ROM), a disk drive, a solid state drive (SSD), a flash memory, and the like. As another example, a non-volatile mass storage device such as a ROM, an SSD, a flash memory, a disk drive, and the like may be included in the computing apparatus 100 as a separate permanent storage device distinct from the memory. In addition, an operating system and at least one program code may be stored in the memory 510.

These software components may be loaded from a computer-readable recording medium separate from the memory 510. Such a separate computer-readable recording medium may include a recording medium directly connectable to the computing apparatus 100, and may include, for example, a computer-readable recording medium such as a floppy drive, a disk, a tape, a DVD/CD-ROM drive, a memory card, and the like. As another example, the software components may be loaded into the memory 510 through the communication module 530 rather than the computer-readable recording medium. For example, at least one program may be loaded into the memory 510 based on a computer program installed by files provided through the communication module 530 by developers or a file distribution system that distributes installation files of applications.

The processor 520 may be configured to process instructions of a computer program by performing basic arithmetic, logic, and input/output operations. The instructions may be provided by the memory 510 or the communication module 530 to another user terminal (not shown) or another external system.

The communication module 530 may provide a configuration or a function for a user terminal (not shown) and the computing apparatus 100 to communicate with each other through a network, and may provide a configuration or a function for the computing apparatus 100 to communicate with an external system (e.g., a separate cloud system, etc.). For example, a control signal, an instruction, data, and the like provided under the control of the processor 520 of the computing apparatus 100 may be transmitted to the user terminal and/or the external system through the communication module 530 and the network, and through the communication module of the user terminal and/or the external system.

In addition, the input/output interface 540 of the computing apparatus 100 may be a means for an interface with an apparatus (not shown) for input or output that is connected to the computing apparatus 100 or that the computing apparatus 100 may include. In FIG. 5, the input/output interface 540 is illustrated as an element configured separately from the processor 520, but is not limited thereto, and the input/output interface 540 may be configured to be included in the processor 520. The computing apparatus 100 may include more components than those of FIG. 5. However, there is no need to clearly illustrate most of the prior art components.

The processor 520 of the computing apparatus 100 may be configured to manage, process, and/or store information and/or data received from a plurality of user terminals and/or a plurality of external systems.

The above-described methods and/or various embodiments may be implemented in digital electronic circuits, computer hardware, firmware, software, and/or combinations thereof. Various embodiments of the present invention may be implemented as a computer program stored on a computer-readable recording medium and/or a computer-readable recording medium, and executed by a data processing device, for example, one or more programmable processors and/or one or more computing apparatuses. The computer program described above may be written in any form of programming language, including compiled or interpreted languages, and may be distributed in any form, such as a standalone program, module, or subroutine. A computer program may be distributed across a single computing apparatus, across multiple computing apparatuses connected through the same network, and/or across multiple distributed computing apparatuses connected through multiple different networks.

The above-described methods and/or various embodiments may be performed by one or more processors configured to execute one or more computer programs that process, store, and/or manage any functions by operating on input data or generating output data. For example, the method and/or various embodiments of the present invention may be performed by a special purpose logic circuit such as an FPGA(Field Programmable Gate Array) or an ASIC(Application Specific Integrated Circuit), and an apparatus and/or system for performing the method and/or embodiments of the present invention may be implemented as a special purpose logic circuit such as an FPGA or an ASIC.

The one or more processors executing the computer program may include a general-purpose or special-purpose microprocessor and/or one or more processors of any type of digital computing apparatus. The processor can receive instructions and/or data from either a read-only memory or a random access memory, or it can receive instructions and/or data from both the read-only memory and the random access memory. In the present invention, components of a computing apparatus performing the methods and/or embodiments may include one or more processors for executing instructions and one or more memory devices for storing instructions and/or data.

According to one embodiment, the computing apparatus can exchange data with one or more mass storage devices for storing data. For example, the computing apparatus may receive data from a magnetic disc or an optical disc, and/or transfer data to a magnetic disc or an optical disc. A computer-readable storage medium suitable for storing instructions and/or data associated with a computer program may include, but is not limited to, any form of non-volatile memory, including semiconductor memory devices such as Erasable Programmable Read-Only Memory (EPROM), Electrically Erasable Programmable Read-Only Memory (EEPROM), and flash memory devices. For example, the computer-readable storage medium may include a magnetic disk, such as an internal hard disk or a removable disk, a magneto-optical disk, and CD-ROM and DVD-ROM disks.

To provide interaction with a user, the computing apparatus may include, but is not limited to, a display device for providing or displaying information to the user, such as a Cathode Ray Tube (CRT), a Liquid Crystal Display (LCD), and the like, and a pointing device through which the user may provide an input, a command, and the like on the computing apparatus, such as a keyboard, a mouse, a trackball, and the like. That is, the computing apparatus may further include any other types of devices for providing interaction with the user. For example, a computing apparatus may provide any form of sensory feedback to a user for interaction with the user, including visual feedback, auditory feedback, and/or tactile feedback. In this regard, a user can provide input to the computing apparatus through various gestures such as sight, sound, and motion.

In the present invention, various embodiments may be implemented in a computing system including a back-end component (for example, a data server), a middleware component (for example, an application server), and/or a front-end component. In this case, the components may be interconnected by any form or medium of digital data communication, such as a communication network. For example, a communication network may include a Local Area Network (LAN) or a Wide Area Network (WAN).

A computing apparatus based on the exemplary embodiments described herein may be implemented using hardware and/or software configured to interact with a user, including a user device, a user interface (UI) device, a user terminal, or a client device. For example, the computing apparatus may include a portable computing apparatus such as a laptop computer. Additionally or alternatively, the computing apparatus may include, but is not limited to, Personal Digital Assistants (PDAs), tablet PCs, game consoles, wearable devices, Internet of Things (IoT) devices, virtual reality (VR) devices, and augmented reality (AR) devices. The computing apparatus may further include other types of devices configured to interact with a user. Additionally, the computing apparatus may include a portable communication device (such as a mobile phone, a smartphone, a wireless cellular phone, and the like) suitable for wireless communication over a network such as a mobile communication network. The computing apparatus may be configured to communicate wirelessly with a network server using wireless communication technologies and/or protocols, such as Radio Frequency (RF), Microwave Frequency (MWF), and/or Infrared Frequency (IR Frequency).

The various embodiments of the present invention, including specific structural and functional details, are exemplary. Therefore, the embodiments of the present invention are not limited to those described above and may be implemented in various other forms. Additionally, the terms used in the present invention are intended to describe some embodiments and are not to be construed as limiting the embodiments. For example, singular words and the like may be interpreted to include the plural as well, unless the context clearly indicates otherwise.

In the present invention, unless otherwise defined, all terms used herein, including technical and scientific terms, shall have the same meaning as commonly understood by those of ordinary skill in the art to which the embodiments pertain. Additionally, commonly used terms, such as terms defined in a dictionary, should be interpreted to have a meaning consistent with their meaning in the context of the relevant technology.

Although the present invention has been described in connection with some embodiments herein, various modifications and changes can be made without departing from the scope of the present invention as understood by those skilled in the art to which the present invention pertains. Furthermore, such modifications and variations should be considered to fall within the scope of the claims appended to this specification.

1. A method for integrated management of facilities based on a digital twin, performed by at least one processor, the method comprising:
obtaining digital twin model data generated based on a first criterion including a modeling rule and a second criterion including a shape and an attribute of an object;
determining whether the obtained digital twin model data satisfies a quality criterion using a plurality of rules; and
registering the digital twin model data in a database when the digital twin model data is determined to satisfy the quality criterion.

2. The method of claim 1, further comprising:
performing monitoring of an actual facility associated with the digital twin model data based on the digital twin model data registered in the database.

3. The method of claim 1, wherein
the determining whether the obtained digital twin model data satisfies the quality criterion comprises:
determining whether each object included in the digital twin model data satisfies at least a portion of the plurality of rules.

4. The method of claim 3, wherein
the determining whether each object included in the digital twin model data satisfies at least a portion of the plurality of rules comprises:
searching for an ID of a first object included in the digital twin model data;
recognizing a shape and an attribute of the object based on the searched ID of the first object; and
determining whether the first object satisfies the quality criterion based on a first set of rules corresponding to the recognized shape and attribute of the first object among the plurality of rules.

5. The method of claim 1, wherein
the digital twin model data is associated with an actual facility, and
the method further comprises:
updating the digital twin model data when a change occurs in the actual facility.

6. The method of claim 5, wherein the updating the digital twin model data comprises:
obtaining sensor data corresponding to the change in the actual facility;
extracting a third object associated with the sensor data from among the respective objects included in the digital twin model data; and
updating the extracted third object based on the obtained sensor data.

7. The method of claim 5, further comprising:
determining whether the updated digital twin model data satisfies the quality criterion using the plurality of rules in response to the digital twin model data being updated.

8. A non-transitory computer-readable recording medium storing instructions for execution by one or more processors that, when executed by the one or more processors, cause the one or more processors to perform the method according to claim 1.

9. A computing apparatus comprising:
a communication module;
a memory; and
at least one processor connected to the memory and configured to execute at least one computer-readable program included in the memory,
wherein
the at least one program includes instructions for:
obtaining digital twin model data generated based on a first criterion including a modeling rule and a second criterion including a shape and an attribute of an object;
determining whether the obtained digital twin model data satisfies a quality criterion using a plurality of rules; and
registering the digital twin model data in a database when the digital twin model data is determined to satisfy the quality criterion.

10. The computing apparatus of claim 9, wherein
the at least one program further includes instructions for:
performing monitoring of an actual facility associated with the digital twin model data based on the digital twin model data registered in the database.

11. The computing apparatus of claim 9, wherein
the at least one program further includes instructions for:
determining whether each object included in the digital twin model data satisfies at least a portion of the plurality of rules.

12. The computing apparatus of claim 11, wherein
the at least one program further includes instructions for:
searching for an ID of a first object included in the digital twin model data;
recognizing a shape and an attribute of the object based on the searched ID of the first object; and
determining whether the first object satisfies the quality criterion based on a first set of rules corresponding to the recognized shape and attribute of the first object among the plurality of rules.

13. The computing apparatus of claim 9, wherein
the digital twin model data is associated with an actual facility, and
the at least one program further includes instructions for:
updating the digital twin model data when a change occurs in the actual facility.

14. The computing apparatus of claim 13, wherein
the at least one program further includes instructions for:
obtaining sensor data corresponding to the change in the actual facility;
extracting a third object associated with the sensor data from among the respective objects included in the digital twin model data; and
updating the extracted third object based on the obtained sensor data.

15. The computing apparatus of claim 13, wherein
the at least one program further includes instructions for:
determining whether the updated digital twin model data satisfies the quality criterion using the plurality of rules in response to the digital twin model data being updated.
